(19) United States
(12) Patent Application Publication
(10) Pub. No.: US 2026/0173315 A1
(43) Pub. Date: Jun. 18, 2026

(54) MAGNETIC FLUID, LIQUID COOLING SYSTEM USING THE SAME, AND COMPONENT CONFIGURATION METHOD FOR LIQUID COOLING SYSTEM

(71) Applicant: INDUSTRIAL TECHNOLOGY RESEARCH INSTITUTE, Hsinchu (TW)

(72) Inventors: Ya-Chi HO, New Taipei City (TW); Tsai-Liang WU, Hsinchu County (TW); Chih-Ya SHEN, Hsinchu City (TW); Da-Jeng YAO, Taipei City (TW)

(73) Assignee: INDUSTRIAL TECHNOLOGY RESEARCH INSTITUTE, Hsinchu (TW)

(21) Appl. No.: 19/049,453

(22) Filed: Feb. 10, 2025

(30) Foreign Application Priority Data
Dec. 16, 2024 (TW) 113148984

(51) Int. Cl. H05K 7/20; G05B 17/02; H01F 1/44

(52) U.S. Cl. CPC H05K 7/20281; G05B 17/02; H01F 1/44

(57) ABSTRACT

The present disclosure provides a magnetic fluid, liquid cooling system using the same and component configuration method for liquid cooling system. The magnetic fluid, adapted to a liquid cooling system, includes a fluid solvent and a magnetic substance. The magnetic substance includes at least one of iron oxide and graphene, a particle size of the magnetic substance ranges from 5 nanometer to 1 millimeter, and a weight percentage of the magnetic substance in the fluid solvent is greater than 0% and not more than 10%. The component configuration method is applicable to an electronic device including the liquid cooling system and electronic components, wherein the liquid cooling system may include a heat dissipation flow channel designed for the passage of the magnetic fluid.

### CROSS-REFERENCE TO RELATED APPLICATIONS

This non-provisional application claims priority under 35 U.S.C. § 119 (a) on Patent Application No(s). 113148984 filed in Republic of China (Taiwan) on Dec. 16, 2024, the entire contents of which are hereby incorporated by reference.

### BACKGROUND

### 1. Technical Field

This disclosure relates to a magnetic fluid, liquid cooling system using the same, and component configuration method for liquid cooling system.

### 2. Related Art

According to statistics, by the end of 2023, there were 40 million electric vehicles on the road globally; and the global server cooling market had already exceeded $2 billion in total value by 2022. In other words, whether for electric vehicles, servers, or other industries requiring cooling systems, the effectiveness of component cooling has become increasingly important.

To design efficient and applicable cooling solutions, engineers from various departments must collaborate closely and repeatedly discuss the structural design and details of the overall system, including the flow mechanism of the cooling liquid and the placement of components. During this process, engineers need to integrate theory with practice, conducting continuous experiments to verify the feasibility and performance of the design, thereby optimizing the overall cooling effect.

### SUMMARY

According to one or more embodiment of this disclosure, a magnetic fluid, adapted to a liquid cooling system, comprises: a liquid solvent and a magnetic substance. The magnetic substance is mixed in the liquid solvent. The magnetic substance comprises at least one of iron oxide and graphene, a particle size of the magnetic substance ranges from 5 nanometer to 1 millimeter, and a weight percentage of the magnetic substance in the fluid solvent is higher than 0% and not higher than 10%.

According to one or more embodiment of this disclosure, a liquid cooling system, configured to load a magnetic fluid, comprises a liquid solvent and a magnetic substance mixed in the liquid solvent, the magnetic substance comprises at least one of iron oxide and graphene, a particle size of the magnetic substance ranges from 5 nanometer to 1 millimeter, and a weight percentage of the magnetic substance in the fluid solvent is higher than 0% and not higher than 10%.

According to one or more embodiment of this disclosure, a component configuration method, adapted to an electronic device comprising a liquid cooling system and a plurality of electronic components, performed by a processing device, and comprises: establishing a first surrogate model and a second surrogate model using a plurality of initial configuration parameter combinations, wherein each of the plurality of initial configuration parameter combinations comprises first configuration data of the liquid cooling system and a plurality of pieces of second configuration data of the plurality of electronic components; selecting a plurality of candidate combinations according to the plurality of initial configuration parameter combinations and performing a determination procedure based on the plurality of candidate combinations, wherein the determination procedure comprises: performing fitting on the plurality of candidate combinations by using the first surrogate model and the second surrogate model to obtain a first fitted curve and a second fitted curve, respectively; and obtaining a target combination from the plurality of candidate combinations according to the first fitted curve and the second fitted curve; outputting a component configuration when an execution count of the determination procedure matches a default count and a simulated cooling result corresponding to the target combination satisfies a default cooling condition; and selecting a plurality of combinations from the plurality of initial configuration parameter combinations based on the target combination as the plurality of candidate combinations to perform the determination procedure again when the execution count of the determination procedure does not match the default count but the simulated cooling result satisfies the default cooling condition.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1A shows the impact of magnetic liquid and non-magnetic liquid on temperatures;

FIG. 1B shows the impact of magnetic liquid and non-magnetic liquid on thermal resistances;

FIG. 2 is a flow chart of a component configuration method for a liquid cooling system according to an embodiment of the present disclosure;

FIG. 3 is a schematic diagram of an electronic device adapted for the component configuration method;

FIG. 4 is a flow chart of selecting candidate combinations for performing a determination procedure again in the component configuration method for a liquid cooling system according to an embodiment of the present disclosure; and

FIG. 5 is a flow chart of selecting a target range in the component configuration method for a liquid cooling system according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

The magnetic fluid according to one or more embodiments of the present disclosure is adapted to a liquid cooling system. The magnetic fluid includes a liquid solvent and a magnetic substance. The magnetic substance is mixed in the liquid solvent. The magnetic substance includes at least one of iron oxide and graphene. A particle size of the magnetic substance ranges from (and includes) 5 nm to 1 mm, and a weight percentage of the magnetic substance in the liquid solvent is higher than 0% and not higher than 10%.

According to the magnetic fluid of the above embodiment, the electromagnetic waves generated by the electronic device may passively (without additional power consumption) induce rapid oscillations of magnetic particles within the magnetic fluid, resulting in inducing turbulence and eddy currents within the magnetic fluid, thereby enhancing the heat dissipation efficiency of the electronic device. Further, the magnetic fluid of the above embodiment is adapted to electronic device that consume high-wattage power.

In an embodiment, the liquid solvent may include at least one of water, acetone, methanol and mineral oil. In addition, the iron oxide may be any one of iron oxide I (Fe₂O), iron oxide II (FeO), iron oxide III (Fe₂O₃) and ferric ferrous oxide (Fe₃O₄). In an embodiment, the magnetic substance may further include carbon nanotube.

Specifically, the type(s) of the magnetic substance, the particle size(s) of the magnetic substance, the weight percentage(s) of the magnetic substance in the liquid solvent and the electromagnetic wave frequency may be as shown in table 1 below. In table 1, the column of the electromagnetic wave frequency is used to represent the frequency at which the corresponding magnetic substance can be excited to generate turbulence and eddy currents.

TABLE 1

| | | concentration | |
|---|---|---|---|
| | | of the magnetic | |
| | | substance | |
| | particle size of | (weight | electromagnetic |
| magnetic | the magnetic | percentage, | wave |
| substance | substance | wt %) | frequency |
| iron oxide I | 0.1 mm to 1.0 | 0.01 to 1.00 | 60 Hz to 2.45 GHz |
| | mm | | |
| iron oxide II | 1 um to 99 um | 0.01 to 5.00 | 60 Hz to 2.45 GHz |
| iron oxide III | 50 nm to 800 nm | 0.01 to 10.00 | 60 Hz to 2.45 GHz |
| graphene | 5 nm to 500 nm | 0.01 to 10.00 | 60 Hz to 2.45 GHz |
| iron oxide | 1 um to 99 um | 0.01 to 2.50 | 60 Hz to 2.45 GHz |
| and graphene | (iron oxide) | (iron oxide) | |
| | 5 nm to 500 nm | 0.01 to 5.00 | |
| | (graphene) | (graphene) | |
| iron oxide | 1 um to 99 um | 0.01 to 2.50 | 60 Hz to 2.45 GHz |
| and carbon | (iron oxide) | (iron oxide) | |
| nanotube | 20 nm to 500 nm | 0.01 to 5.00 | |
| | (carbon nanotube) | (carbon nanotube) | |
| iron oxide, | 1 um to 99 um | 0.01 to 2.50 | 60 Hz to 2.45 GHz |
| graphene and | (iron oxide) | (iron oxide) | |
| carbon | 5 nm to 500 nm | 0.01 to 5.00 | |
| nanotube | (graphene) | (graphene) | |
| | 20 nm to 500 nm | 0.01 to 5.00 | |
| | (carbon nanotube) | (carbon nanotube) | |

As shown in table 1 above, the magnetic substance may only include iron oxide, and the weight percentage of iron oxide in the liquid solvent ranges from 0.01% to 10%; the magnetic substance may only include graphene, and the weight percentage of graphene in the liquid solvent ranges from 0.01% to 10%, the magnetic substance may include both the 5 iron oxide and graphene, and the weight percentage of iron oxide in the liquid solvent ranges from 0.01% to 2.5%, the weight percentage of graphene in the liquid solvent ranges from 0.01% to 5%, the magnetic substance may include both iron oxide and carbon nanotube, and the weight percentage of iron oxide in the liquid solvent ranges from (and includes) 0.01% to 2.5%, the weight percentage of carbon nanotube in the liquid solvent ranges from (and includes) 0.01% to 5%; the magnetic substance may include both iron oxide, graphene and carbon nanotube, and the weight percentage of iron oxide in the liquid solvent ranges from (and includes) 0.01% to 2.5%, the weight percentage of graphene in the liquid solvent ranges from (and includes) 0.01% to 5%, the weight percentage of carbon nanotube in the liquid solvent ranges from (and includes) 0.01% to 5%.

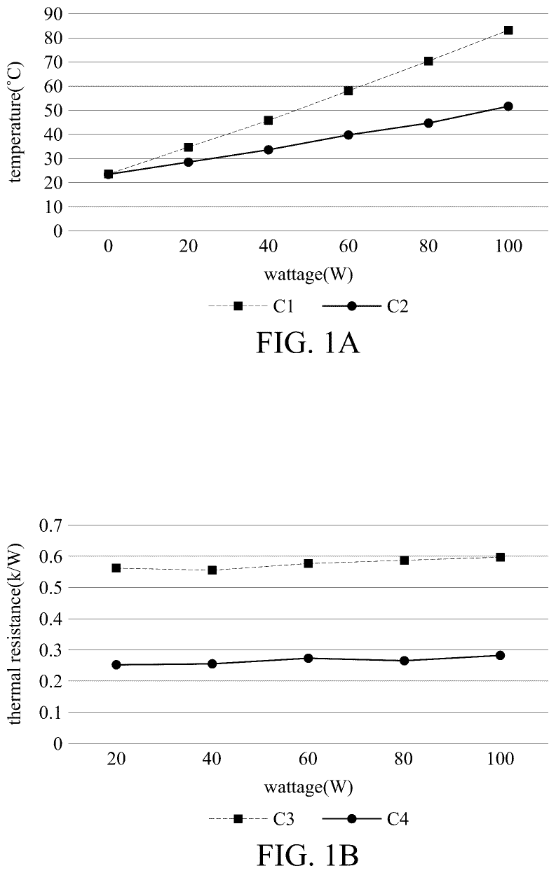

Please refer to FIG. 1A and FIG. 1B, wherein FIG. 1A shows the impact of magnetic liquid and non-magnetic liquid on temperatures, and FIG. 1B shows the impact of magnetic liquid and non-magnetic liquid on thermal resistances. FIG. 1A and FIG. 1B are results obtained by testing electronic device of high-power power supply. The magnetic substance in the magnetic fluid of FIG. 1A and FIG. 1B includes iron oxide (Fe₃O₄), graphene and carbon nanotube, the non-magnetic fluid only includes the liquid solvent. The range of the particle size of the magnetic fluid of FIG. 1A and FIG. 1B is between (and includes) 1 millimeter and 5 nanometer, and the liquid solvent includes water, acetone, methanol and mineral oil. In FIG. 1A, curve C1 is used to represent the result of selecting the non-magnetic fluid as the cooling liquid of the liquid cooling system, and curve C2 is used to represent the result of selecting the magnetic fluid described above as the cooling liquid of the liquid cooling system. As shown in FIG. 1A, the higher the operating power of the electronic device is, the higher the temperature of the electronic device is. Further, according to curve C1 of the non-magnetic fluid and curve C2 of the magnetic fluid, when magnetic fluid is used as the cooling liquid, the temperature rise of the electronic device is lower than that when non-magnetic fluid is used as the cooling liquid.

In addition, in FIG. 1B, curve C3 is used to represent the result of selecting the non-magnetic fluid as the cooling liquid of the liquid cooling system, and curve C4 is used to represent the result of selecting the magnetic fluid described above as the cooling liquid of the liquid cooling system. As shown in FIG. 1B, the higher the operating power of the electronic device is, the higher the thermal resistance of the electronic device is. Further, according to curve C3 of the non-magnetic fluid and curve C4 of the magnetic fluid, when magnetic fluid is used as the cooling liquid, the thermal resistance of the electronic device is lower than that when non-magnetic fluid is used as the cooling liquid. According to FIG. 1B, the thermal resistance of curve C4 is 50% lower than the thermal resistance of curve C3.

In FIG. 1A and FIG. 1B, due to the presence of a large transformer in high-power power supply, the transformer generates a time-varying electromagnetic field. Therefore, selecting magnetic fluid to dissipate heat in high-power power supply may achieve better cooling performance. Accordingly, the magnetic fluid described in one or more of the above embodiments may rapidly facilitate heat exchange between the electronic device and the magnetic fluid, thereby effectively reducing the operating temperature and thermal resistance of the electronic device.

The present disclosure further proposes a liquid cooling system using the magnetic fluid described above. Further, the liquid cooling system may be implemented as a cooling liquid channel, and the liquid cooling system may be configured to carry the magnetic fluid of one or more embodiments described above and for the magnetic fluid of one or more embodiments described above to flow through. The liquid cooling system according to one or more embodiments of the present disclosure is adapted to the electronic device consuming high-wattage power, and the heat exchange between the electronic device and the magnetic fluid may be rapidly achieved, thereby effectively reducing the temperature and thermal resistance of the electronic device in operation.

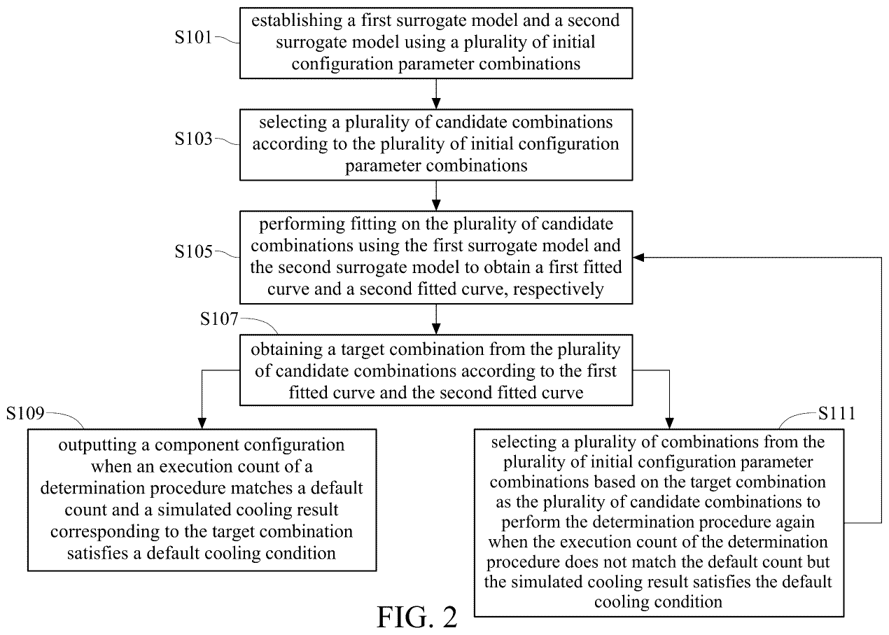

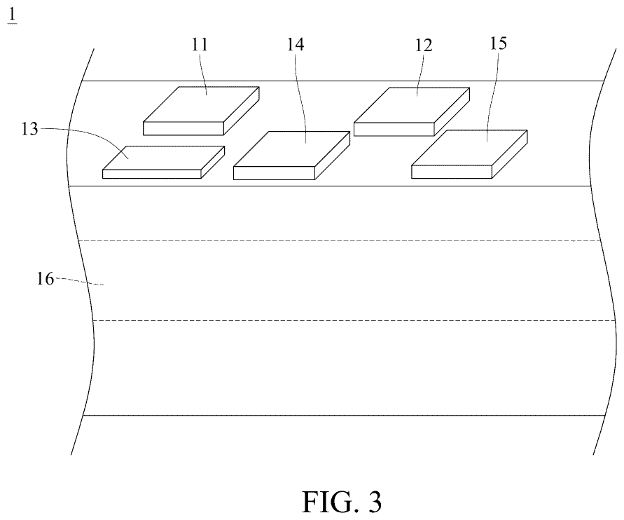

Please refer to FIG. 2 and FIG. 3, wherein FIG. 2 is a flow chart of a component configuration method for a liquid cooling system according to an embodiment of the present disclosure, and FIG. 3 is a schematic diagram of an electronic device adapted for the component configuration method. The component configuration method according to an embodiment of the present disclosure is adapted to an electronic device 1 including an electronic component 11, an electronic component 12, an electronic component 13, an electronic component 14, an electronic component 15 and a liquid cooling system 16. Further, the electronic device 1 may be one or more devices that generate high amounts of heat during operation, such as a mobile device, a tablet, a desktop computer, a server, a large database center, an electric vehicle, a drone, a solar panel and a high-power chip etc. For example, the electronic components 11 to 15 may be communication components that generate electromagnetic waves and components that generate heat, such as Bluetooth component, Wifi component, ZigBee component, converter and battery etc. The type of the electronic device 1, the types of the electronic components 11 to 15 and the number of the electronic components 11 to 15 are merely examples, the present disclosure is not limited thereto. The liquid cooling system 16 may be the liquid cooling system described above, and the liquid cooling system 16 may be implemented as a cooling liquid channel. FIG. 3 illustrates the liquid cooling system 16 as a cooling liquid channel disposed inside the electronic device 1 and located under the electronic components 11 to 15, and the magnetic fluid of one or more embodiments described above may be loaded in the liquid cooling system 16 and flow through the liquid cooling system 16 to cool the electronic components 11 to 15.

In the present embodiment, the component configuration method for the liquid cooling system is performed by a processing device. The processing device may include one or more processors, the processor is, for example, a central processing unit (CPU), a graphics processing unit (GPU), a microcontroller, a programmable logic controller (PLC), or other processors with signal processing functions.

As shown in FIG. 2, the component configuration method includes step S101: establishing a first surrogate model and a second surrogate model using a plurality of initial configuration parameter combinations; step S103: selecting a plurality of candidate combinations according to the plurality of initial configuration parameter combinations; step S105: performing fitting on the plurality of candidate combinations by using the first surrogate model and the second surrogate model to obtain a first fitted curve and a second fitted curve, respectively; step S107: obtaining a target combination from the plurality of candidate combinations according to the first fitted curve and the second fitted curve; step S109: outputting a component configuration when an execution count of a determination procedure matches a default count and a simulated cooling result corresponding to the target combination satisfies a default cooling condition; and step S111: selecting a plurality of combinations from the plurality of initial configuration parameter combinations based on the target combination as the plurality of candidate combinations to perform the determination procedure again when the execution count of the determination procedure does not match the default count but the simulated cooling result satisfies the default cooling condition. Step S105 and step S107 may be regarded as the determination procedure.

In step S101, the processing device uses the initial configuration parameter combinations to build the first surrogate model and the second surrogate model. The processing device may obtain the initial configuration parameter combinations through random sampling or latin hypercube sampling (LHS). Each of the initial configuration parameter combinations includes first configuration data of the liquid cooling system 16 and a plurality of pieces of second configuration data of the electronic components 11 to 15. The first configuration data may include one or more of the position depth, extension length, width, flow channel mechanism, and flow channel shape (e.g., single flow channel, U-shaped flow channel, or multi-U-shaped flow channel) of the cooling liquid channel of the liquid cooling system 16 within the electronic device 1. Each of the pieces of second configuration data may include one or more of the corresponding electronic component's dimensions (size), coordinates on the electronic device 1, the operating frequency band of the electronic component, the phase of the electromagnetic wave signal generated by the electronic component, the maximum transmission rate of the electronic component, and the transmission distance of the electronic component. The first surrogate model may be one of a Kriging model and a kernel partial least squares (KPLS) model, and the second surrogate model may be another one of the Kriging model and the kernel partial least squares (KPLS) model.

The initial configuration parameter combinations may be arranged according to the variables of the first configuration data or the variables of the second configuration data. Take the first configuration data for example, the initial configuration parameter combinations with close (similar) variables of the first configuration data may be adjacent to each other.

In step S103, the processing device selects multiple combinations from the initial configuration parameter combinations as the candidate combinations. For example, the processing device may select said multiple combinations from the initial configuration parameter combinations as the candidate combinations according to a user command.

In step S105 and S107, the processing device performs the determination procedure based on the candidate combinations. In step S105, the processing device uses the first surrogate model to perform fitting on the candidate combinations to obtain the first fitted curve, and uses the second surrogate model to perform fitting on the candidate combinations to obtain the second fitted curve. The first fitted curve and the second fitted curve may each be a curved formed by a plurality of candidate combinations. The following refers the candidate combinations on each of the first fitted curve and the second fitted curve as fitted combinations.

In step S107, the processing device obtains the target combination from the first fitted curve and the second fitted curve. The target combination may correspond to an optimal solution of the first fitted curve and the second fitted curve. Further, the processing device may determine the operating performance of each of the fitted combinations of each of the first fitted curve and the second fitted curve. The operating performance may include electromagnetic field performance, thermal flow field performance, and/or cooling performance. The processing device may select one of the fitted combinations with an operating performance that best matches the expected performance as the target combination. For example, the electromagnetic field performance may include the turbulence and eddy current intensity of the magnetic fluid, the thermal flow field performance may include the heat conduction conditions of each of the electronic components 11 to 15, and the cooling performance may include the temperature of each of the electronic components 11 to 15. The expected performance corresponding to the electromagnetic field performance may include achieving the highest turbulence and eddy current intensity, the expected performance corresponding to the thermal flow field performance may include achieving the lowest level of heat conduction from other electronic components, and the expected performance corresponding to the cooling performance may include achieving the lowest average temperature of the electronic components 11 to 15. The operating performances and the expected performances listed above are examples, the present disclosure is not limited thereto.

After step S107, the processing device may count the execution count of the determination procedure. For example, the processing device may add 1 to the execution count. An initial value of the execution count may be 0. Further, the processing device may use a simulation software (for example, Ansys) to perform simulation on the target combination to obtain the simulated cooling result corresponding to the target combination.

In step S109, when the processing device determines that the execution count of the determination procedure is equal to the default count and the simulated cooling result corresponding to the target combination satisfies the default cooling condition, the processing device outputs the corresponding component configuration. The component configuration may be the target combination. The default count may be 1000, but the present disclosure is not limited thereto. The default cooling condition may include a temperature upper limit of each of the electronic components and/or a default upper limit of an average temperature of the electronic components etc.

In step S111, when the processing device determines that the execution count of the determination procedure is smaller than the default count but the simulated cooling result corresponding to the target combination satisfies the default cooling condition, the processing device selects, based on the target combination, a plurality of combinations including the target combination from the initial configuration parameter combinations, and uses the plurality of combinations as a plurality of candidate combinations. The processing device performs the determination procedure (i.e. step S105) again on the candidate combinations selected in step S111.

Accordingly, the component configuration method according to one or more embodiments of the present disclosure may be used to obtain the locations of the components of the electronic device and the optimal configuration of the cooling liquid channel in a shortened computation duration, and improved heat dissipation effect may be obtained. In addition, the correctness of the result generated by the surrogate models may be verified by determining whether the simulated cooling result satisfies the default cooling condition.

It should be noted that the greater the execution count of the determination procedure is, the closer the first fitted curve and the second fitted curve are to each other. That is, the degree of overlapping between the first fitted curve and the second fitted curve may be higher.

In an embodiment, when the execution count of the determination procedure is equal to the default count but the simulated cooling result corresponding to the target combination does not satisfy the default cooling condition, among one or more target combinations with the simulated cooling results satisfying the default cooling condition, the processing device may select one of said one or more target combinations with the simulated cooling result best matching the default cooling condition to output the corresponding component configuration. In an embodiment, when the execution count of the determination procedure is smaller than the default count and the simulated cooling result corresponding to the target combination does not satisfy the default cooling condition, the processing device may abandon this target combination and perform step S101 again. For example, the processing device may remove the target combination from the initial configuration parameter combinations, and use the initial configuration parameter combinations excluding the target combination to build the first surrogate model and the second surrogate model. Alternatively, the processing device may abandon this target combination and perform step S107 again to select another target combination.

In the embodiment of step S107, the processing device may obtain a plurality of target combinations from the first fitted curve and the second fitted curve; and in step S111, among the target combinations, the processing device may use the initial configuration parameter combinations as the candidate combinations, wherein the initial configuration parameter combinations selected as the candidate combinations include combination(s) having the first configuration data (or the second configuration data) with the highest variable and the lowest variable and combination(s) having the first configuration data (or the second configuration data) with variables between the highest variable and the lowest variable.

Therefore, even when the gap between the execution count of the determination procedure and the default count is still large (i.e., during the early stages of executing the component configuration method), the difference between the simulated cooling result corresponding to the target combination and the default cooling condition may also be significant. However, according to one or more embodiments of the component configuration method of the present disclosure, through the repeated use of the first surrogate model and the second surrogate model for rapid calculations, as the gap between the execution count of the determination procedure and the default count decreases (i.e., during the later stages of executing the component configuration method), the difference between the simulated cooling result corresponding to the target combination and the default cooling condition may also be reduced.

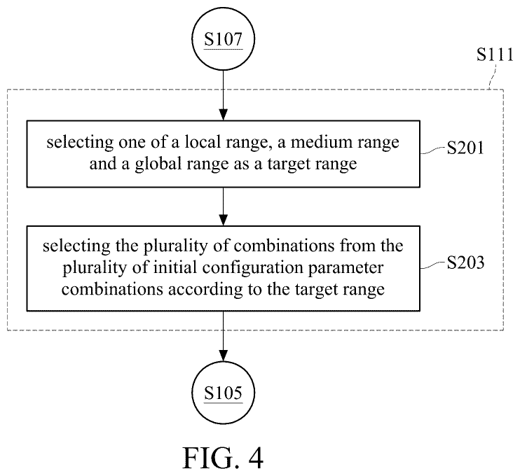

Please refer to FIG. 4, wherein FIG. 4 is a flow chart of selecting candidate combinations for performing a determination procedure again in the component configuration method for a liquid cooling system according to an embodiment of the present disclosure. FIG. 4 may be regarded as a detailed flow chart of step S111 of FIG. 2. As shown in FIG. 4, selecting the candidate combinations used for performing the determination procedure again may include: step S201: selecting one of a local range, a medium range and a global range as a target range; and step S203: selecting the plurality of combinations from the plurality of initial configuration parameter combinations according to the target range.

In step S201, the processing device may use any one of the local range, the medium range and the global range as the target range. The global range is larger than the medium range, and the medium range is larger than the local range. Further, the boundary values of the global range are greater than the boundary values of the medium range, and the boundary values of the medium range are greater than the boundary values of the local range, wherein the boundary value may correspond to the variable described above. The local range, the medium range and the global range indicate ranges are used for selecting the plurality of combinations from the initial configuration parameter combinations.

In step S203, the processing device may select the plurality of combinations from the initial configuration parameter combinations that fall within the target range, and the plurality of combinations include the target combination. For example, the processing device may use the target combination as the center of the target range, select the initial configuration parameter combinations that fall within the target range, and use the initial configuration parameter combinations that fall within the target range as well as the target combination as the candidate combinations for performing the determination procedure again. As described above, the initial configuration parameter combinations with similar variables may be adjacent (close) to each other. Accordingly, the processing device may select the initial configuration parameter combinations that are close to the target combination.

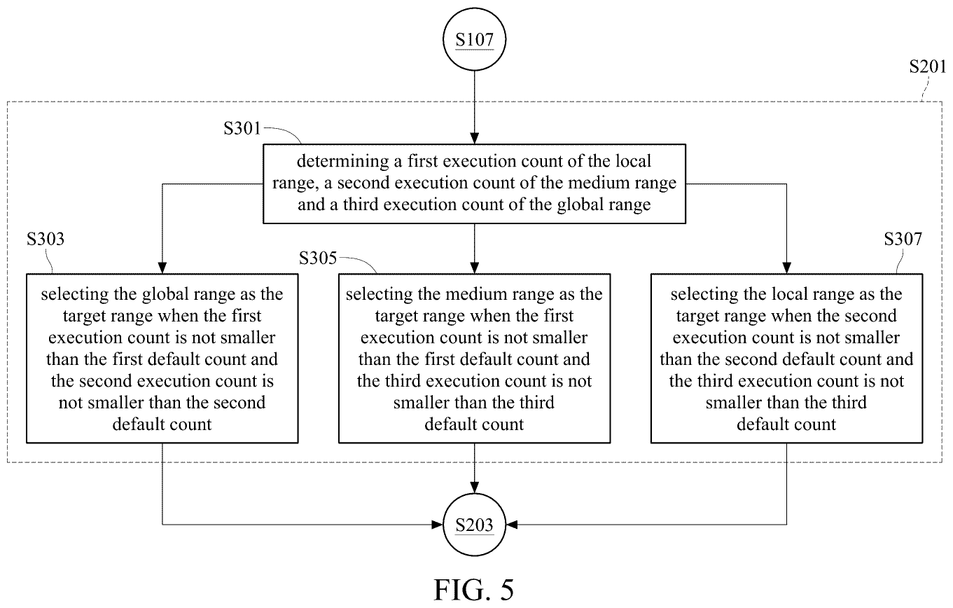

Please refer to FIG. 5, wherein FIG. 5 is a flow chart of selecting a target range in the component configuration method for a liquid cooling system according to an embodiment of the present disclosure. FIG. 5 may be regarded as a detailed flow chart of step S201 of FIG. 4. As shown in FIG. 5, selecting the target range may include: step S301: determining a first execution count of the local range, a second execution count of the medium range and a third execution count of the global range; step S303: selecting the global range as the target range when the first execution count of the local range is not smaller than the first default count and the second execution count of the medium range is not smaller than the second default count; step S305: selecting the medium range as the target range when the first execution count of the local range is not smaller than the first default count and the third execution count of the global range is not smaller than the third default count; and step S307: selecting the local range as the target range when the second execution count of the medium range is not smaller than the second default count and the third execution count of the global range is not smaller than the third default count.

In step S301, the processing device may determine the first execution count of the local range, the second execution count of the medium range and the third execution count of the global range. The processing device may count the corresponding execution count every time the corresponding one of the local range, the medium range and the global range is selected as the target range. For example, the processing device may add 1 to the execution count. The initial value of each of the first execution count, the second execution count and the third execution count may be 0.

In step S303, when the processing device determines that the first execution count of the local range is not smaller than the first default count and the second execution count of the medium range is not smaller than the second default count, the processing device may use the global range as the target range, wherein the third execution count of the global range at the moment is smaller than the third default count.

In step S305, when the processing device determines that the first execution count of the local range is not smaller than the first default count and the third execution count of the global range is not smaller than the third default count, the processing device may use the medium range as the target range, wherein the second execution count of the medium range at the moment is smaller than the second default count.

In step S307, when t the processing device determines that the second execution count of the medium range is not smaller than the second default count and the third execution count of the global range is not smaller than the third default count, the processing device may use the local range as the target range, wherein the first execution count of the local range at the moment is smaller than the first default count.

In other words, the processing device may determine the sampling range (global range, medium range, or local range) based on the remainder of the iteration count. Additionally, when the first execution count for the local range is equal to the first default count, the second execution count for the medium range is equal to the second default count, and the third execution count for the global range is equal to the third default count, the processing device may determine that the execution count of the aforementioned determination process matches the default count. When the first execution count for the local range is less than the first default count, the second execution count for the medium range is less than the second default count, and the third execution count for the global range is less than the third default count, the processing device may select the target range in the following sequence: local range, medium range, local range, global range, local range.

The first default count may be greater than the second default count and the third default count, the second default count may equal the third default count. A ratio between the first default count, the second default count and the third default count may be 3:1:1.

Accordingly, by selecting one of the local range, the medium range and the global range as the target range according to the respective execution count of the local range, the medium range and the global range, local optimum situation may be avoided, sampling range may be balanced, and sampling accuracy may be improved.

In view of the above, according to the magnetic fluid of the above embodiment, the electromagnetic waves generated by the electronic device may passively (without additional power consumption) induce rapid oscillations of magnetic particles within the magnetic fluid, resulting in inducing turbulence and eddy currents within the magnetic fluid, thereby enhancing the heat dissipation efficiency of the electronic device. Further, the magnetic fluid of one or more embodiments described above and the liquid cooling system loaded with the magnetic fluid are adapted to electronic device that consume high-wattage power, and heat exchange between the electronic device and the magnetic fluid may be rapidly facilitated, thereby effectively reducing the operating temperature and thermal resistance of the electronic device. The component configuration method according to one or more embodiments of the present disclosure may be used to determine the proper locations of the components of the electronic device and the optimal configuration of the cooling liquid channel in a shortened computation duration, and improved heat dissipation effect may be obtained. In addition, the correctness of the result generated by the surrogate models may be verified by determining whether the simulated cooling result satisfies the default cooling condition. In the component configuration method, by selecting one of the local range, the medium range and the global range as the target range according to the respective execution count of the local range, the medium range and the global range, local optimum situation may be avoided, sampling range may be balanced, and sampling accuracy may be improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A magnetic fluid, adapted to a liquid cooling system, comprising:
a liquid solvent; and
a magnetic substance mixed in the liquid solvent, the magnetic substance comprising at least one of iron oxide and graphene, a particle size of the magnetic substance ranging from 5 nanometer to 1 millimeter, and a weight percentage of the magnetic substance in the fluid solvent being higher than 0% and not higher than 10%.

2. The magnetic fluid according to claim 1, wherein the magnetic substance comprises the iron oxide, and a weight percentage of the iron oxide in the liquid solvent is 0.01% to 10%.

3. The magnetic fluid according to claim 1, wherein the magnetic substance comprises the graphene, and a weight percentage of the graphene in the liquid solvent is 0.01% to 10%.

4. The magnetic fluid according to claim 1, wherein the magnetic substance comprises the iron oxide and the graphene, a weight percentage of the iron oxide in the liquid solvent is 0.01% to 2.5%, and a weight percentage of the graphene in the liquid solvent is 0.01% to 5%.

5. The magnetic fluid according to claim 1, wherein the magnetic substance further comprises carbon nanotube.

6. The magnetic fluid according to claim 5, wherein the magnetic substance comprises the iron oxide and the carbon nanotube, a weight percentage of the iron oxide in the liquid solvent is 0.01% to 2.5%, and a weight percentage of the carbon nanotube in the liquid solvent is 0.01% to 5%.

7. The magnetic fluid according to claim 5, wherein the magnetic substance comprises the iron oxide, the graphene and the carbon nanotube, a weight percentage of the iron oxide in the liquid solvent is 0.01% to 2.5%, a weight percentage of the graphene in the liquid solvent is 0.01% to 5%, and a weight percentage of the carbon nanotube in the liquid solvent is 0.01% to 5%.

8. The magnetic fluid according to claim 1, wherein the liquid solvent comprises at least one of water, acetone, methanol and mineral oil.

9. A liquid cooling system, configured to load a magnetic fluid, the magnetic fluid comprising a liquid solvent and a magnetic substance mixed in the liquid solvent, the magnetic substance comprising at least one of iron oxide and graphene, a particle size of the magnetic substance ranging from 5 nanometer to 1 millimeter, and a weight percentage of the magnetic substance in the fluid solvent being higher than 0% and not higher than 10%.

10. A component configuration method, adapted to an electronic device comprising a liquid cooling system and a plurality of electronic components, performed by a processing device, and comprising:
establishing a first surrogate model and a second surrogate model using a plurality of initial configuration parameter combinations, wherein each of the plurality of initial configuration parameter combinations comprises first configuration data of the liquid cooling system and a plurality of pieces of second configuration data of the plurality of electronic components;
selecting a plurality of candidate combinations according to the plurality of initial configuration parameter combinations and performing a determination procedure based on the plurality of candidate combinations, wherein the determination procedure comprises:
performing fitting on the plurality of candidate combinations by using the first surrogate model and the second surrogate model to obtain a first fitted curve and a second fitted curve, respectively; and
obtaining a target combination from the plurality of candidate combinations according to the first fitted curve and the second fitted curve;
outputting a component configuration when an execution count of the determination procedure matches a default count and a simulated cooling result corresponding to the target combination satisfies a default cooling condition; and
selecting a plurality of combinations from the plurality of initial configuration parameter combinations based on the target combination as the plurality of candidate combinations to perform the determination procedure again when the execution count of the determination procedure does not match the default count but the simulated cooling result satisfies the default cooling condition.

11. The component configuration method according to claim 10, wherein selecting the plurality of combinations from the plurality of initial configuration parameter combinations based on the target combination as the plurality of candidate combinations comprises:
selecting one of a local range, a medium range and a global range as a target range; and
selecting the plurality of combinations from the plurality of initial configuration parameter combinations according to the target range, and the plurality of combinations comprising the target combination,
wherein the global range is larger than the medium range, and the medium range is larger than the local range.

12. The component configuration method according to claim 11, wherein selecting one of the local range, the medium range and the global range as the target range comprises:
selecting the global range as the target range when a first execution count of the local range is not smaller than a first default count and a second execution count of the medium range is not smaller than a second default count;
selecting the medium range as the target range when the first execution count of the local range is not smaller than the first default count and a third execution count of the global range is not smaller than a third default count; and
selecting the local range as the target range when the second execution count of the medium range is not smaller than the second default count and the third execution count of the global range is not smaller than the third default count,
wherein the first default count is greater than the second default count and the third default count, and the second default count is greater than the third default count.

13. The component configuration method according to claim 10, wherein the first surrogate model is one of a Kriging model and a kernel partial least squares model, and the second surrogate model is another one of the Kriging model and the kernel partial least squares model.
